(19) United States
(12) Patent Application Publication
(10) Pub. No.: US 2025/0092507 A1
(43) Pub. Date: Mar. 20, 2025

(54) APPARATUS FOR PHYSICAL VAPOUR DEPOSITION OF METALLIC ACTIVE MATERIAL ANODES

(71) Applicant: Li-Metal Corp., Markhan (CA)

(72) Inventors: Maciej Jastrzebski, Toronto (CA); Kristyn M. Zoschke, Markham (CA)

(21) Appl. No.: 18/884,592

(22) Filed: Sep. 13, 2024

Related U.S. Application Data
(60) Provisional application No. 63/583,226, filed on Sep. 15, 2023.

(51) Int. Cl. C23C 14/26; C23C 14/04; C23C 14/50

(52) U.S. Cl. CPC C23C 14/26; C23C 14/042; C23C 14/505

(57) ABSTRACT

A physical vapour deposition apparatus includes: a rotating drum carrying a substrate; a molten metal bath spaced from the substrate; a metal vapour conduit extending between the molten metal bath and the substrate, the metal vapour conduit having at least one wall; and temperature control elements configured to control a temperature of the at least one wall.

### CROSS-REFERENCE TO RELATED APPLICATION

This application claims the benefit of U.S. Provisional Application No. 63/583,226 filed Sep. 15, 2023, the content of which is incorporated herein by reference in its entirety.

### FIELD

The subject disclosure relates generally to physical vapour deposition and in particular, to an apparatus for physical vapour deposition of metallic active material anodes.

### BACKGROUND

In the field of high-energy density battery fabrication, materials such as lithium, sodium, or other alkali metals or alkaline earth metals, are often used to provide high-energy anodes. Such materials are typically deposited, along with other materials, as layered thin films on suitable substrates to provide anodes comprising a first current collector, an anode active material, a separator, a cathode active material, and a second current collector. The anode assembly is typically immersed in a liquid electrolyte, or in the case of solid-state batteries, a solid electrolyte layer is incorporated into the separator and cathodic active material, to yield the high-energy density battery cell.

Thin films of electrode materials are typically deposited using physical vapour deposition (PVD) apparatus, in which an anode active material (such as lithium) is evaporated onto both sides of a substrate, such as copper, that serves as a current collector.

FIGS. 1A and 1B show a conventional PVD apparatus, which is generally indicated by reference numeral 20. The PVD apparatus 20 is an evaporative PVD apparatus, and comprises a metal vapour source 22 that is placed in proximity to a chilled, rotating drum 24 carrying a substrate 26 onto which metal vapour is deposited as a thin film. To achieve high productivity, the metal vapour source 22 is in the form of a molten metal bath 28. Metal vapour is directed from the metal vapour source 22 toward the drum 24 and substrate 26 by a metal vapour conduit 32 (sometimes referred to in the art as a “chimney”). The metal vapour conduit 32 typically has a rectangular or square cross section, and is typically spaced from the substrate 26 by a gap 34. This gap 34 allows the substrate to be moved past the metal vapour conduit 32 without contacting possible metal buildup formed on edges of the metal vapour conduit 32, which would otherwise damage the substrate 26 and thereby cause loss of product. The PVD apparatus 20 is typically housed in a vacuum chamber (not shown) and is operated at well below atmospheric pressure, typically on the order of about 104 Pa or less. Operating the PVD apparatus 20 at this reduced pressure allows metal vapour flux to travel directly from the molten metal bath 28 to the substrate 26 generally unimpededly, and in a line-of-sight manner along a path (sometimes referred to as a “trajectory”) that is typically straight.

One disadvantage of conventional PVD apparatuses, such as PVD apparatus 20 is that the substrate can experience non-uniformity in deposition rate. As will be understood, such non-uniformity arises due to unequal distances of points on the surface of the substrate 26 from a given point on the surface of the molten metal bath 28. For example, as shown in FIG. 1A, the deposition rate at the central region A of the substrate 26 is higher than the deposition rate at the edge region B of the substrate 26, because the edge region B is, on average, further from the surface of the molten metal bath 28 than the central region A.

In particular, and with reference to FIG. 1A, the central region A receives flux contributions from elements on the surface of the molten metal bath 28 that are 1 unit and 2 units away, along the axis indicated as “x”. Specifically, the central region A receives flux contributions from two elements located 1 x unit away, and two elements located 2 x units away. In contrast, the edge region B receives flux contributions from elements that are 1 x unit away, 2 x units away, 3 x units away and 4 x units away. As will be understood, the edge region B receives flux contributions equal to only 50% of those of central region A, from elements that are 1 x units and 2 x units away, in addition to flux contributions of reduced magnitude (owing to greater distance and hence narrower range of incident angles) from elements that are 3 x units and 4 x units away. A comparison of flux contributions is provided in Table 1:

TABLE 1

| | Number of Elements | Number of elements |
|---|---|---|
| | Providing | providing |
| Bath element | Contribution at | contribution at Edge |
| distance (x units) | Central Region A | Region B |
| 1 | 2 | 1 |
| 2 | 2 | 1 |
| 3 | | 1 |
| 4 | | 1 |

As a result, the deposition rate at central region A is greater than that at edge region B, resulting in a convex and non-uniform thickness profile across the width of the substrate 26. When integrated into a battery cell, the convex thickness profile gives rise to problems as the resistance and available active metal differ at different parts of the anode, leading to non-uniformities in stripping plating and creating difficulties in maintaining uniform pressure on the cell, which in turn can lead to lower cycle-life and difficulties in assembly.

Another disadvantage of conventional PVD apparatuses, such as PVD apparatus 20, is leakage of metal vapour flux through gap 34, which can result in formation of a metal deposit on the substrate 26 outside of the metal vapour conduit 32, commonly referred to as “edge bleed”.

For example, as shown in FIGS. 2A and 2B, metal vapour flux path 42, which corresponds to metal vapour emitted from an outermost edge of the surface of the molten metal bath 28, and metal vapour flux path 44, which corresponds to metal vapour redirected (such as after desorption or collision) by the walls of the metal vapour conduit 32, exit through the gap 34 and form a deposit in an edge bleed region 46 of the substrate 26.

As will be understood, such “edge bleed” deposits interfere with attachment of current collecting terminal tabs to the anode, and generally require removal in order to achieve adequate bonding and sealing, particularly for “pouch-type” battery cells.

Improvements are generally desired. It is an object at least to provide a novel apparatus for physical vapour deposition of metallic active material anodes.

### SUMMARY OF THE INVENTION

Accordingly, in one aspect there is provided a physical vapour deposition apparatus comprising: a rotating drum carrying a substrate; a molten metal bath spaced from the substrate; a metal vapour conduit extending between the molten metal bath and the substrate, the metal vapour conduit having at least one wall; and temperature control elements configured to control a temperature of the at least one wall.

The temperature control elements may comprise at least one of: a resistive heating element; an induction heating susceptor; a coolant fluid circuit; and a combination thereof. The temperature control elements may be configured to heat the at least one wall to above a melting point of metal in the molten metal bath. The metal vapour conduit may be sized and positioned such that metal condensation on at least one wall flows downwardly along the surface of the at least one wall into the molten metal bath. The at least one wall may be spaced from the substrate to define a gap therebetween. The gap may be less than 5 mm. The gap may be less than 3 mm. The gap may be less than 2 mm.

In another aspect, there is provided a physical vapour deposition apparatus comprising: a rotating drum carrying a substrate; a molten metal bath spaced from the substrate; and a mask disposed between the substrate and the molten metal bath, the mask defining an aperture through which metal vapour flux passes to reach the substrate, the aperture and the substrate each having a respective width that is less than a width of the molten metal bath.

A portion of the mask surrounding the aperture may block the metal vapour flux from reaching the substrate. The mask may be substantially parallel to the substrate. The mask may be substantially parallel to a surface of the molten metal bath. The mask may be disposed closer to the substrate than to the molten metal bath. The mask may be spaced less than 5 mm from the substrate. The mask may be spaced less than 3 mm from the substrate. The mask may be spaced less than 2 mm from the substrate.

The apparatus may further comprise a metal vapour conduit extending between the molten metal bath and the substrate, the metal vapour conduit having at least one wall. The mask may comprise at least one flange extending inwardly from the at least one wall, the at least one flange defining the aperture. The apparatus may further comprise temperature control elements configured to control a temperature of at least one of: said at least one wall; and the mask. The temperature control elements may comprise at least one of: a resistive heating element; an induction heating susceptor; a coolant fluid circuit; and a combination thereof. The temperature control elements may be configured to heat at least one of said at least one wall and the mask, to above a melting point of metal in the molten metal bath.

In another aspect, there is provided a physical vapour deposition apparatus comprising: a rotating drum carrying a substrate; a molten metal bath spaced from the substrate; a metal vapour conduit extending between the molten metal bath and the substrate, the metal vapour conduit having at least one wall; and at least one longitudinal slat disposed within the metal vapour conduit.

The at least one longitudinal slat may be oriented substantially perpendicularly to a surface of the molten metal bath. The at least one longitudinal slat may be a single longitudinal slat positioned directly above a midpoint of a width of the molten metal bath. The single longitudinal slat may have a length that is greater than 0.7 times a spacing of the molten metal bath from the substrate.

The at least one longitudinal slat may comprise a plurality of longitudinal slats, each having a respective length that is greater than 0.7 times a spacing of the molten metal bath from the substrate.

The at least one wall may be spaced from the substrate to define a gap therebetween. The at least one longitudinal slat may be sized and positioned to block metal vapour flux from entering the gap. The gap may be less than 5 mm. The gap may be less than 3 mm. The gap may be less than 2 mm. The at least one longitudinal slat may comprise a longitudinal slat positioned laterally adjacent said gap. The longitudinal slat may be positioned directly above a first side of a midpoint of a width of the molten metal bath, the longitudinal slat being sized and positioned to block metal vapour flux emitted from a second side of the midpoint of the width of the molten metal bath from entering the gap.

The apparatus may further comprise temperature control elements configured to control a temperature of at least one of: said at least one wall; and said at least one longitudinal slat. The temperature control elements may comprise at least one of: a resistive heating element; an induction heating susceptor; a coolant fluid circuit; and a combination thereof. The temperature control elements may be configured to heat at least one of said at least one wall and the at least one longitudinal slat, to above a melting point of metal in the molten metal bath.

### BRIEF DESCRIPTION OF THE DRAWINGS

Embodiments will now be described more fully with reference to the accompanying drawings in which:

FIGS. 1A and 1B are schematic views of a conventional physical vapour deposition apparatus, showing metal vapour flux paths impinging on different regions of a substrate;

FIG. 2A is a schematic view of the conventional physical vapour deposition apparatus of FIGS. 1A and 1B, showing metal vapour flux paths impinging on an “edge bleed” region of the substrate;

FIG. 2B is an enlarged fragmentary view of the conventional physical vapour deposition apparatus of FIG. 2A;

FIGS. 3A and 3B are schematic views of a physical vapour deposition apparatus in accordance with the present invention;

FIGS. 4A and 4B are schematic views of another embodiment of a physical vapour deposition apparatus in accordance with the present invention;

FIGS. 5A and 5B are schematic views of still another embodiment of a physical vapour deposition apparatus in accordance with the present invention;

FIG. 6A is a schematic view of still yet another embodiment of a physical vapour deposition apparatus in accordance with the present invention; and

FIG. 6B is an enlarged fragmentary view of the physical vapour deposition apparatus of FIG. 6A.

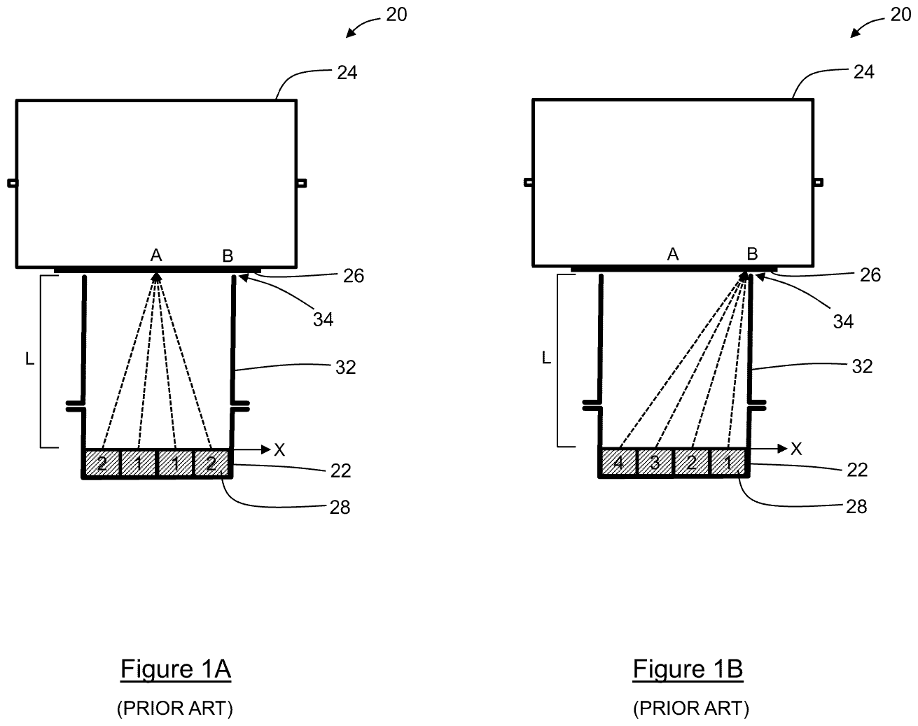

### DETAILED DESCRIPTION OF THE EMBODIMENTS

The foregoing summary, as well as the following detailed description of certain examples will be better understood when read in conjunction with the appended drawings. As used herein, an element or feature introduced in the singular and preceded by the word “a” or “an” should be understood as not necessarily excluding the plural of the elements or features. Further, references to “one example” or “one embodiment” are not intended to be interpreted as excluding the existence of additional examples or embodiments that also incorporate the described elements or features. Moreover, unless explicitly stated to the contrary, examples or embodiments “comprising” or “having” or “including” an element or feature or a plurality of elements or features having a particular property may include additional elements or features not having that property. Also, it will be appreciated that the terms “comprises”, “has”, “includes” means “including by not limited to” and the terms “comprising”, “having” and “including” have equivalent meanings.

As used herein, the term “and/or” can include any and all combinations of one or more of the associated listed elements or features.

It will be understood that when an element or feature is referred to as being “on”, “attached” to, “connected” to, “coupled” with, “contacting”, etc. another element or feature, that element or feature can be directly on, attached to, connected to, coupled with or contacting the other element or feature or intervening elements may also be present. In contrast, when an element or feature is referred to as being, for example, “directly on”, “directly attached” to, “directly connected” to, “directly coupled” with or “directly contacting” another element of feature, there are no intervening elements or features present.

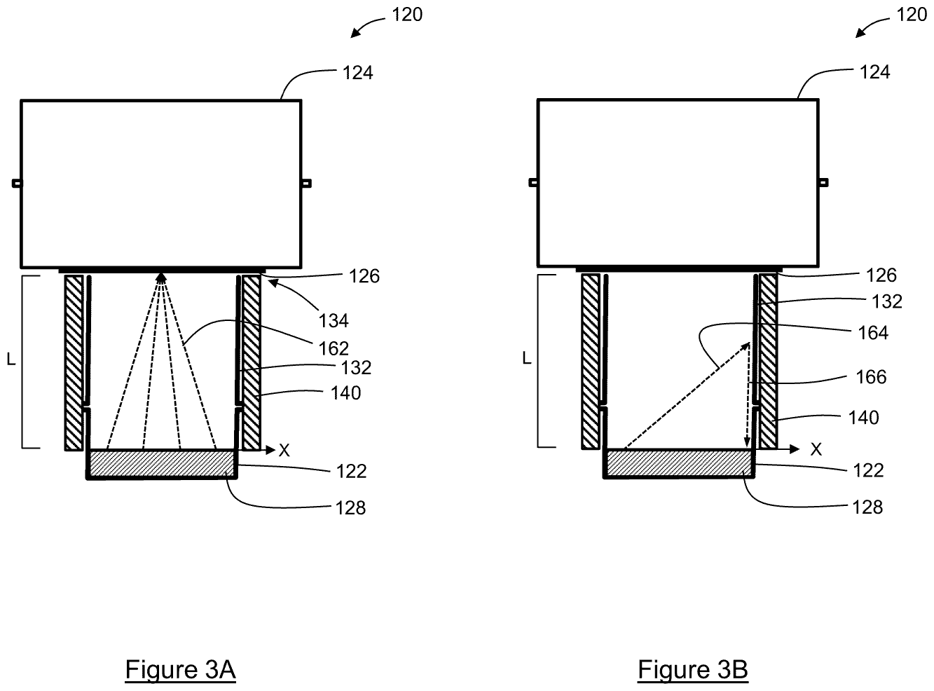

Turning now to FIGS. 3A and 3B, a PVD apparatus is shown and is generally indicated by reference numeral 120. The PVD apparatus 120 is an evaporative PVD apparatus, and comprises a metal vapour source 122 that is placed in proximity to a chilled, rotating drum 124 carrying a substrate 126 onto which metal vapour is deposited as a thin film. The thin film may, for example, form part of a metallic active material anode (not shown) forming part of a high-energy density battery cell (not shown). The metal vapour source 122 is in the form of a molten metal bath 128 comprising an open volume of molten metal. The molten metal may be, for example, any of Na, Mg, Al, Li, Zn, Ca, K, or Si. Metal vapour is directed from the metal vapour source 122 toward the drum 124 and substrate 126 by a metal vapour conduit 132 (sometimes referred to in the art as a “chimney”).

The PVD apparatus 120 is housed in a vacuum chamber (not shown) and is operated at below atmospheric pressure, such as for example on the order of about 10-4 Pa or less. Operating the PVD apparatus 120 at reduced pressure allows metal vapour flux to travel directly from the molten metal bath 128 to the substrate 126 generally unimpededly, and in a line-of-sight manner along a path that is generally straight.

The metal vapour conduit 132 has a rectangular or square cross section, and has upper edges that are spaced from the substrate 126 by a gap 134. The gap 134 allows the substrate to be moved past the metal vapour conduit 132 without contacting possible metal buildup formed on edges of the metal vapour conduit 132, which would otherwise damage the substrate 126 and thereby cause loss of product. In the example shown, the gap 134 is less than 5 mm, and is preferably less than 3 mm and more preferably less than 2 mm.

In this embodiment, the metal vapour conduit 132 comprises thermal control means 140 for maintaining the metal vapour conduit 132 at a temperature that is substantially lower than the temperature of the molten metal bath 128, but above the melting point of the metal contained in molten metal bath 128. The thermal control means 140 may, for example, include features for active or passive heating, such as one or more resistive heating elements, one or more induction heating susceptors and induction heater, or the like, and/or active or passive cooling, such as one or more Peltier cooling elements, one or more coolant fluid circuits, or ambient cooling, any of which may for example be controlled by suitable temperature control structure. In the example shown, the thermal control means 140 extend the height L of the metal vapour conduit 132, and comprise resistive heating windings (not shown) in communication with one or more thermocouples (not shown) and with suitable temperature control structure (not shown). Additionally, in the example shown, the metal contained in molten metal bath 128 is lithium, and the walls of the metal vapour conduit 132 are maintained at a temperature in the range of from about 180.5° C. to about 600° C., and preferably in the range of from about 190° C. to about 250° C.

As will be understood, maintaining the walls of the metal vapour conduit 132 at a temperature above the melting point of the metal contained in molten metal bath 128 reduces the likelihood of metal vapour being redirected or “remitted” therefrom, and promotes condensation and subsequent surface flow of condensed molten metal downwardly to the bath 128. For example, metal vapour flux having high incident angles, such as that of metal vapour flux path 162, is emitted from the molten metal bath 128 and reaches the substrate 126 directly, where it forms a metal deposit. In contrast, metal vapour flux having low incident angles, such as that of metal vapour flux path 164, is emitted from the molten metal bath 128 and impinges on the heated wall of the metal vapour conduit 132, where it condenses and eventually flows downwardly along the surface of the wall as surface flow 166 into the molten metal bath 128.

As will be appreciated, by reducing the amount of metal vapour flux having low incident angles that reaches the substrate 126, the profile of the metal film deposited on the substrate can be better controlled.

The temperature may be constant along the lengths of the walls of the metal vapour conduit 132, or may vary as a function of distance along one or more of those lengths, such as in the form of a temperature gradient.

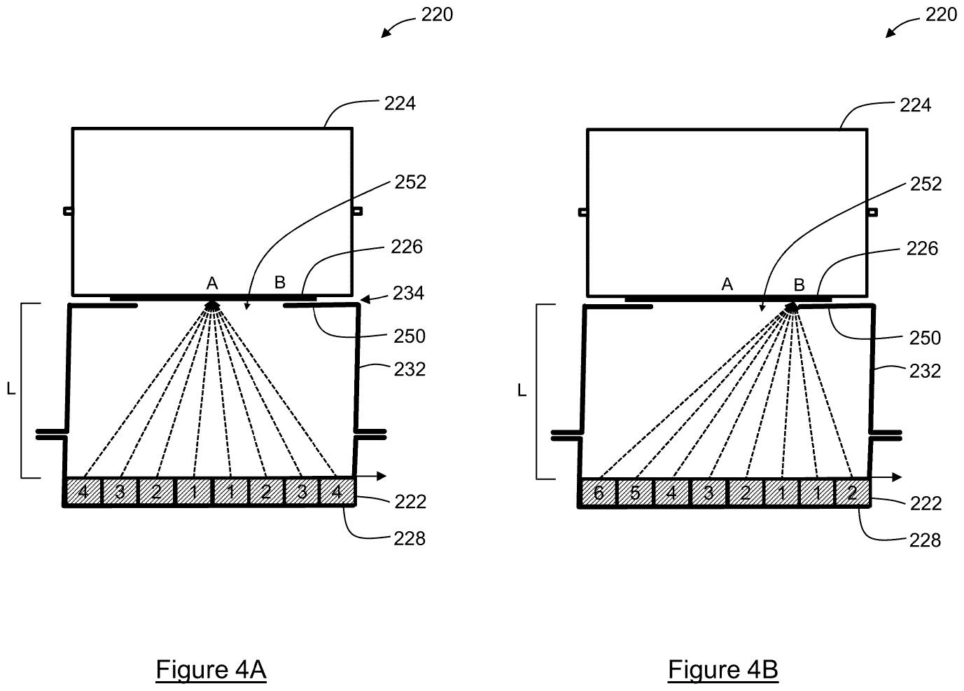

In other embodiments, the PVD apparatus may be differently configured. For example, FIGS. 4A and 4B show another embodiment of a PVD apparatus, which is generally indicated by reference numeral 220. The PVD apparatus 220 is an evaporative PVD apparatus, and comprises a metal vapour source 222 that is placed in proximity to a chilled, rotating drum 224 carrying a substrate 226 onto which metal vapour is deposited as a thin film. The thin film may, for example, form part of a metallic active material anode (not shown) forming part of a high-energy density battery cell (not shown). The metal vapour source 222 is in the form of a molten metal bath 228 comprising an open volume of molten metal. The molten metal may be, for example, any of Na, Mg, Al, Li, Zn, Ca, K, or Si. Metal vapour is directed from the metal vapour source 222 toward the drum 224 and substrate 226 by a metal vapour conduit 232 or “chimney”. The PVD apparatus 220 is housed in a vacuum chamber (not shown) and is operated at below atmospheric pressure, such as for example on the order of about 104 Pa or less.

The metal vapour conduit 232 has a rectangular or square cross section, and has upper edges that are spaced from the substrate 226 by a gap 234, similar to gap 134 described above. In the example shown, the gap 234 is less than 5 mm, and is preferably less than 3 mm and more preferably less than 2 mm.

The metal vapour conduit 232 comprises a mask 250 in the form of one or more flanges that extend inwardly from the walls of the metal vapour conduit 232. The mask 250 defines an aperture 252 through which the metal vapour flux travels to reach the substrate 226. As will be appreciated, the one or more flanges of the mask 250 define a discrete area on the substrate 226 on which deposition is focused. In the example shown, the mask 250 is spaced less than 5 mm from the substrate 226, and is preferably spaced less than 3 mm from the substrate 226 and more preferably less than 2 mm from the substrate 226.

In this embodiment, the molten metal bath 228 is sized such that it has a width that is greater than the width of the aperture 252. The molten metal bath 228 may have a width that is at least 1.2 times the width of the aperture 252, and preferably the molten metal bath 228 has a width that is at least 1.5 times the width of the aperture 252, more preferably greater than 1.5 times the width of the aperture 252. In the example shown, the molten metal bath 228 has a width that is about 2.0 times the width of the aperture 252.

The greater width of the molten metal bath 228 relative to the width of the aperture 252 advantageously improves uniformity between the central region A and the edge region B of the substrate 226. As will be understood, the edge region B receives flux contributions equal to 100% of those of central region A, from elements that are 1 x, units and 2 x units away, and 50% from elements that are 3 x units and 4 x units away. A comparison of flux contributions is provided in Table 2:

TABLE 2

| | Number of Elements | Number of elements |
|---|---|---|
| | Providing | providing |
| Bath element | Contribution at | contribution at Edge |
| distance (x units) | Central Region A | Region B |
| 1 | 2 | 2 |
| 2 | 2 | 2 |
| 3 | 2 | 1 |
| 4 | 2 | 1 |
| 5 | | 1 |
| 6 | | 1 |

Although not shown in FIGS. 4A and 4B, the PVD apparatus 220 comprises thermal control means (not shown) for maintaining the metal vapour conduit 232 and the mask 250 at a temperature that is substantially lower than the temperature of the molten metal bath 228, but above the melting point of the metal contained in molten metal bath 228. The thermal control means are similar to thermal control means 140 described above, and may, for example, include features for active or passive heating, such as one or more resistive heating elements, one or more induction heating susceptors and induction heater, or the like, and/or active or passive cooling, such as one or more Peltier cooling elements, one or more coolant fluid circuits, or ambient cooling, any of which may for example be controlled by suitable temperature control structure. As will be understood, maintaining the walls of the metal vapour conduit 232 and the mask 250 at a temperature above the melting point of the metal contained in molten metal bath 228 reduces the likelihood of metal vapour being redirected or “remitted” therefrom, and promotes condensation and eventual downward surface flow back down to the molten metal bath 228. In this manner, the actual behaviour of the source more closely conforms to that described above, and results in a more uniform deposit profile. In the example shown, the metal contained in molten metal bath 228 is lithium, and the walls of the metal vapour conduit 232 and the mask 250 are maintained at a temperature in the range of from about 180.5° C. to about 600° C., and preferably in the range of from about 190° C. to about 250° C. The temperatures of the walls of the metal vapour conduit 232 and the mask 250 may be the same or different. The temperature may be constant along the lengths of the walls of the metal vapour conduit 232 and along the lengths of the flanges of the mask 250, or may vary as a function of distance along one or more of those lengths, such as in the form of a temperature gradient.

In other embodiments, the PVD apparatus 220 may be differently configured. For example, although in the embodiment described above, both the walls of the metal vapour conduit 232 and the mask 250 are subjected to temperature control, in other embodiments, only the walls of the metal vapour conduit 232, or only the mask 250, may be subject to temperature control. In still other embodiments, neither the walls of the metal vapour conduit 232 nor the mask 250 may be subject to temperature control.

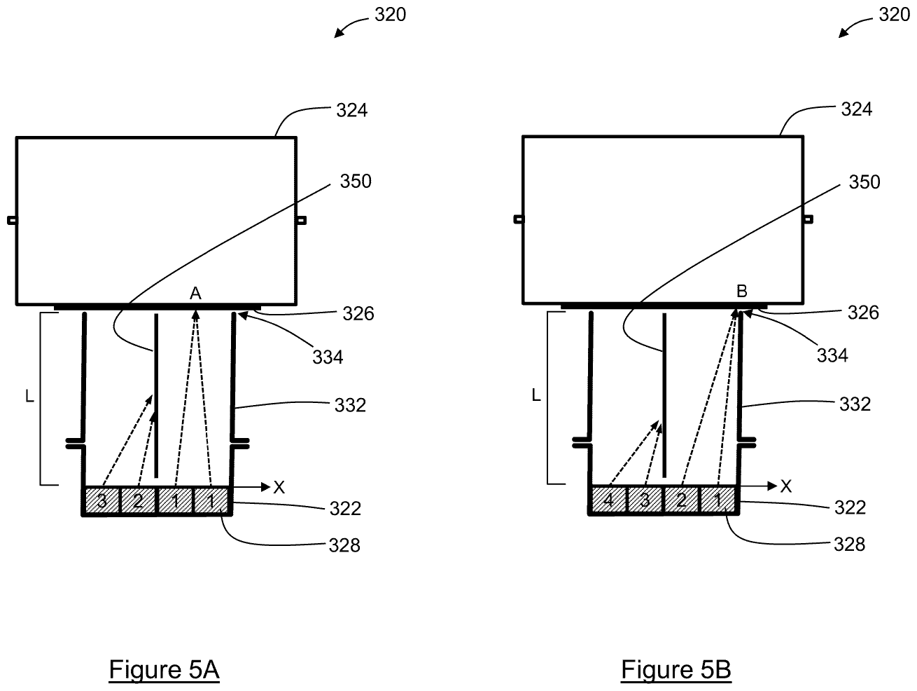

FIGS. 5A and 5B show another embodiment of a PVD apparatus, which is generally indicated by reference numeral 320. The PVD apparatus 320 is an evaporative PVD apparatus, and comprises a metal vapour source 322 that is placed in proximity to a chilled, rotating drum 324 carrying a substrate 326 onto which metal vapour is deposited as a thin film. The thin film may, for example, form part of a metallic active material anode (not shown) forming part of a high-energy density battery cell (not shown). The metal vapour source 322 is in the form of a molten metal bath 328 comprising an open volume of molten metal. The molten metal may be, for example, any of Na, Mg, Al, Li, Zn, Ca, K, or Si. Metal vapour is directed from the metal vapour source 322 toward the drum 324 and substrate 326 by a metal vapour conduit 332 or “chimney”. The PVD apparatus 320 is housed in a vacuum chamber (not shown) and is operated at below atmospheric pressure, such as for example on the order of about 10⁻⁴ Pa or less.

The metal vapour conduit 332 has a rectangular or square cross section, and has upper edges that are spaced from the substrate 326 by a gap 334. In the example shown, the gap 334 is less than 5 mm, and is preferably less than 3 mm and more preferably less than 2 mm.

In this embodiment, the PVD apparatus 320 comprises one or more guide plates or slats 350 that each extend at least a portion of the height H of the metal vapour conduit 332 and are each oriented generally perpendicularly to the surface of the molten metal bath 328. Each of the one or more slats 350 is configured to block or serve as a barrier to lower angle metal vapour flux, so as to reduce deposition rate non-uniformity experienced by the substrate 326. As will be understood, for a two-dimensional source, the deposition rate contribution D of a given bath element can be approximated as a function of distance x along the bath surface, by the following formula:

$$D = IA \frac{1}{{( Δ {x}^{2} + {( H )}^{2} )}^{\frac{k}{2}}} \qquad ( 1 )$$

where Δx is the distance along the bath surface between the bath element and a point on the bath surface beneath a point of interest on substrate; H is the distance from the bath surface to the substrate; A is the area of the bath element; I is the source intensity; and k is a distance decay exponent having a value of between 1 and 2, depending on the source geometry. As can be seen from equation (1), for a small value of Δx relative to H, the impact on deposition rate contribution is small, while for large values of Δx relative to the same H, the impact on deposition rate contribution is more significant, giving rise to deposition rate non-uniformities between small and large values of Ax.

The one or more slats 350 block the contribution of large Δx bath elements, and thereby improve deposition rate uniformity across the substrate 326. In the example shown, the PVD apparatus 320 comprises a single slat 350 that is centered along the width of the surface of the bath 328, has a length that is about 0.9 times the length L of the metal vapour conduit 332, and has upper and lower edges that are spaced from the surface of the bath 328 and from the substrate 326 by first and second gaps.

Although not shown in FIGS. 5A and 5B, the PVD apparatus 320 comprises thermal control means (not shown) for maintaining the metal vapour conduit 332 and the one or more slats 350 at a temperature that is substantially lower than the temperature of the molten metal bath 328, but above the melting point of the metal contained in molten metal bath 328. The thermal control means are similar to thermal control means 140 described above, and may, for example, include features for active or passive heating, such as one or more resistive heating elements, one or more induction heating susceptors and induction heater, or the like, and/or active or passive cooling, such as one or more Peltier cooling elements, one or more coolant fluid circuits, or ambient cooling, any of which may for example be controlled by suitable temperature control structure. As will be understood, maintaining the walls of the metal vapour conduit 332 and the one or more slats 350 at a temperature above the melting point of the metal contained in molten metal bath 328 reduces the likelihood of metal vapour being redirected or “remitted” therefrom, and promotes condensation and eventual downward surface flow back down to the molten metal bath 328. In this manner, the actual behaviour of the source more closely conforms to that described above, and results in a more uniform deposit profile. In the example shown, the metal contained in molten metal bath 328 is lithium, and the walls of the metal vapour conduit 332 and the one or more slats 350 are maintained at a temperature in the range of from about 180.5° C. to about 600° C., and preferably in the range of from about 190° C. to about 250° C. The temperatures of the walls of the metal vapour conduit 332 and the one or more slats 350 may be the same or different. The temperature may be constant along the lengths of the walls of the metal vapour conduit 332 and along the lengths of the one or more slats 350, or may vary as a function of distance along one or more of those lengths, such as in the form of a temperature gradient.

In other embodiments, the PVD apparatus 320 may be differently configured. For example, although in the embodiment described above, both the walls of the metal vapour conduit 332 and the one or more slats 350 are subjected to temperature control, in other embodiments, only the walls of the metal vapour conduit 332 or only the one or more slats 350, may be subject to temperature control. In still other embodiments, neither the walls of the metal vapour conduit 332 nor the one or more slats 350 may be subject to temperature control.

Although in the embodiment described above, the PVD apparatus 320 comprises a single slat 350 that is centered along the width of the surface of the bath 328, in other embodiments, the PVD apparatus may alternatively comprise two or more slats at different locations along the width of the bath.

Although in the embodiment described above, the slat 350 has a length that is about 0.9 times the length L of the metal vapour conduit 332, in other embodiments, each slat may alternatively length ranging from 0.7 times the length L of the metal vapour conduit 332 to about 0.99 times the length L of the metal vapour conduit 332, provided each slat is sized such that it has upper and lower edges that can still be spaced from the surface of the bath 328 and from the substrate 326 by first and second gaps.

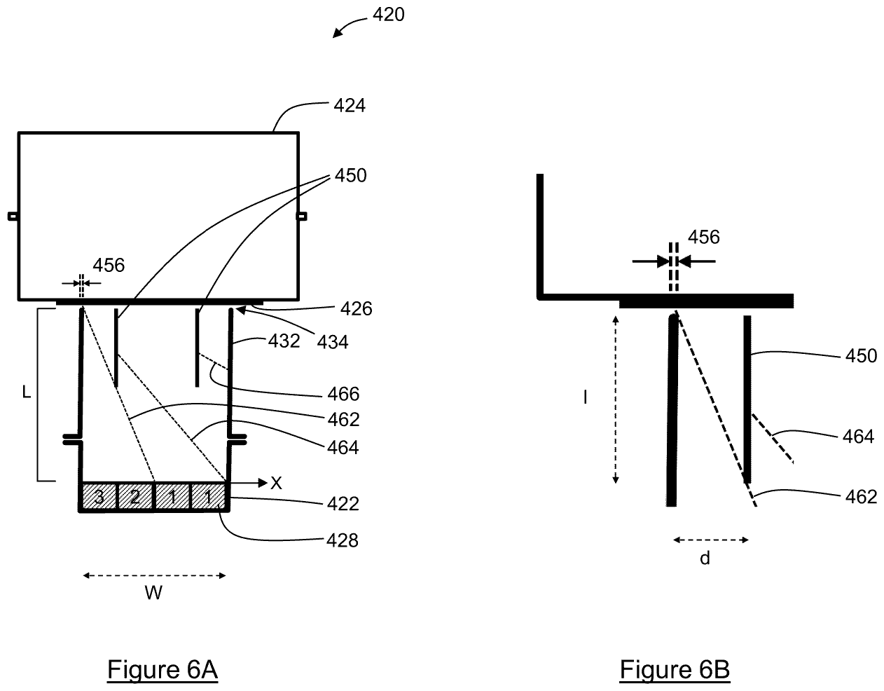

FIGS. 6A and 6B show another embodiment of a PVD apparatus, which is generally indicated by reference numeral 420. The PVD apparatus 420 is an evaporative PVD apparatus, and comprises a metal vapour source 422 that is placed in proximity to a chilled, rotating drum 424 carrying a substrate 426 onto which metal vapour is deposited as a thin film. The thin film may, for example, form part of a metallic active material anode (not shown) forming part of a high-energy density battery cell (not shown). The metal vapour source 422 is in the form of a molten metal bath 428 comprising an open volume of molten metal. The molten metal may be, for example, any of Na, Mg, Al, Li, Zn, Ca, K, or Si. Metal vapour is directed from the metal vapour source 422 toward the drum 424 and substrate 426 by a metal vapour conduit 432 or “chimney”. The PVD apparatus 420 is housed in a vacuum chamber (not shown) and is operated at below atmospheric pressure, such as for example on the order of about 10⁻⁴ Pa or less.

The metal vapour conduit 432 has a rectangular or square cross section, and has upper edges that are spaced from the substrate 426 by a gap 434. The gap 434 allows the substrate to be moved past the metal vapour conduit 432 without contacting possible metal buildup formed on edges of the metal vapour conduit 432, which would otherwise damage the substrate 426 and thereby cause loss of product. In the example shown, the gap 434 is less than 5 mm, and is preferably less than 3 mm and more preferably less than 2 mm.

In this embodiment, the PVD apparatus 420 comprises one or more guide plates or slats 450 that extend a portion of the height L of the metal vapour conduit 432 and are each oriented generally perpendicularly to the surface of the molten metal bath 428. Each of the slats 450 is configured to block or serve as a barrier to lower angle metal vapour flux, and thereby reduce the angular range over which line-of-sight metal vapour flux can enter the gap 434, to in turn reduce the width and thickness of metal deposited in an edge bleed region 456 of the substrate 426.

In the example shown, the PVD apparatus 420 comprises two slats 450 located at generally off-center positions across the width of the metal vapour conduit 432. Each slat 450 is sized such that metal vapour flux at incident angles lower than that of metal vapour flux path 462, which corresponds to metal vapour emitted from the center or midpoint of the width of the bath 428 (namely, at 0.5 times the width W of the vapour conduit 432), is blocked by the slat 450 and therefore does not enter the gap 434. Expressed geometrically, in the example shown, if the metal vapour conduit 432 has an upper edge that is a height L above the surface of the bath 428, and a width W along which the bath 428 is centered, then for a spacing d of each slat 450 from the wall of the metal vapour conduit 432, the downward edge of the slat 450 is spaced a distance/from the top of the metal vapour conduit 432, whereby L/0.5·W=1/d. In other words, in the example shown, the downward edge of the slat 450 is spaced above the surface of the bath 428 by a distance of (L−l).

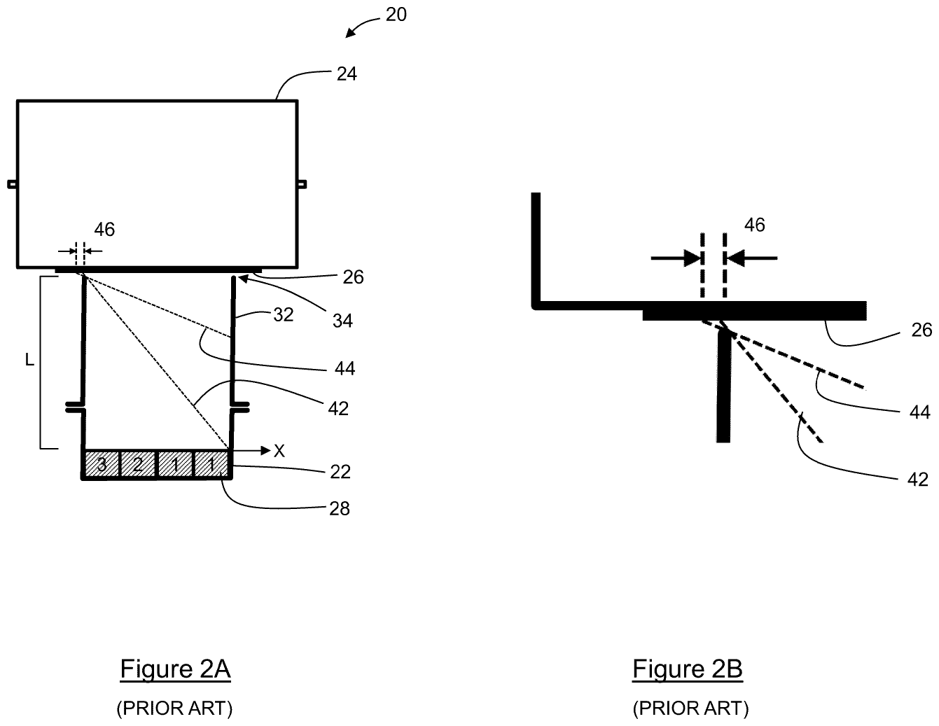

As a result of this sizing, metal vapour flux path 364, which originates from a point on the surface of the bath 428 beyond the geometric center, and metal vapour flux path 466, which corresponds to metal vapour redirected (such as after desorption or collision) by the walls of the metal vapour conduit 432, are blocked by the slat 450 and are therefore do not enter the gap 434 or contribute to any metal deposit in the edge bleed region 456. As will be appreciated, due to the presence of slat 450, the width of the edge bleed region 456 is advantageously narrower than edge bleed regions of conventional PVD apparatuses, such as edge bleed region 46 of conventional PVD apparatus 20 shown in FIGS. 2A and 2B.

Although not shown in FIGS. 6A and 6B, the PVD apparatus 420 comprises thermal control means (not shown) for maintaining the metal vapour conduit 432 and the one or more slats 450 at a temperature that is substantially lower than the temperature of the molten metal bath 428, but above the melting point of the metal contained in molten metal bath 428. The thermal control means are similar to thermal control means 140 described above, and may, for example, include features for active or passive heating, such as one or more resistive heating elements, one or more induction heating susceptors and induction heater, or the like, and/or active or passive cooling, such as one or more Peltier cooling elements, one or more coolant fluid circuits, or ambient cooling, any of which may for example be controlled by suitable temperature control structure. As will be understood, maintaining the walls of the metal vapour conduit 432 and the one or more slats 450 at a temperature above the melting point of the metal contained in molten metal bath 428 reduces the likelihood of metal vapour being redirected or “remitted” therefrom, and promotes condensation and eventual downward surface flow back down to the molten metal bath 428. In this manner, the actual behaviour of the source more closely conforms to that described above, and results in a more uniform deposit profile. In the example shown, the metal contained in molten metal bath 428 is lithium, and the walls of the metal vapour conduit 432 and the one or more slats 450 are maintained at a temperature in the range of from about 180.5° C. to about 600° C., and preferably in the range of from about 190° C. to about 250° C. The temperatures of the walls of the metal vapour conduit 432 and the one or more slats 450 may be the same or different. The temperature may be constant along the lengths of the walls of the metal vapour conduit 432 and along the lengths of the one or more slats 450, or may vary as a function of distance along one or more of those lengths, such as in the form of a temperature gradient.

In other embodiments, the PVD apparatus 420 may be differently configured. For example, although in the embodiment described above, both the walls of the metal vapour conduit 432 and the one or more slats 450 are subjected to temperature control, in other embodiments, only the walls of the metal vapour conduit 432 or only the one or more slats 450, may be subject to temperature control. In still other embodiments, neither the walls of the metal vapour conduit 432 nor the one or more slats 450 may be subject to temperature control.

Although embodiments have been described above with reference to the accompanying drawings, those of skill in the art will appreciate that variations and modifications may be made without departing from the scope thereof as defined by the appended claims.

What is claimed is:

1. A physical vapour deposition apparatus comprising:
a rotating drum carrying a substrate;
a molten metal bath spaced from the substrate;
a metal vapour conduit extending between the molten metal bath and the substrate, the metal vapour conduit having at least one wall; and
temperature control elements configured to control a temperature of the at least one wall.

2. The physical vapour deposition apparatus of claim 1, wherein the temperature control elements comprise at least one of: a resistive heating element; an induction heating susceptor; a coolant fluid circuit; and a combination thereof.

3. The physical vapour deposition apparatus of claim 1, wherein the temperature control elements are configured to heat the at least one wall to above a melting point of metal in the molten metal bath.

4. The physical vapour deposition apparatus of claim 1, wherein the metal vapour conduit is sized and positioned such that metal condensation on at least one wall flows downwardly along the surface of the at least one wall into the molten metal bath.

5. The physical vapour deposition apparatus of claim 1, wherein the at least one wall is spaced from the substrate to define a gap therebetween.

6. The physical vapour deposition apparatus of claim 5, wherein the gap is less than 5 mm.

7. A physical vapour deposition apparatus comprising:
a rotating drum carrying a substrate;
a molten metal bath spaced from the substrate; and
a mask disposed between the substrate and the molten metal bath, the mask defining an aperture through which metal vapour flux passes to reach the substrate, the aperture and the substrate each having a respective width that is less than a width of the molten metal bath.

8. The physical vapour deposition apparatus of claim 7, wherein a portion of the mask surrounding the aperture blocks the metal vapour flux from reaching the substrate.

9. The physical vapour deposition apparatus of claim 7, wherein the mask is disposed closer to the substrate than to the molten metal bath.

10. The physical vapour deposition apparatus of claim 7, further comprising a metal vapour conduit extending between the molten metal bath and the substrate, the metal vapour conduit having at least one wall.

11. The physical vapour deposition apparatus of claim 10, wherein the mask comprises at least one flange extending inwardly from the at least one wall, the at least one flange defining the aperture.

12. The physical vapour deposition apparatus of claim 10, further comprising temperature control elements configured to control a temperature of at least one of:
said at least one wall; and
the mask.

13. A physical vapour deposition apparatus comprising:
a rotating drum carrying a substrate;
a molten metal bath spaced from the substrate;
a metal vapour conduit extending between the molten metal bath and the substrate, the metal vapour conduit having at least one wall; and
at least one longitudinal slat disposed within the metal vapour conduit.

14. The physical vapour deposition apparatus of claim 13, wherein the at least one longitudinal slat is oriented substantially perpendicularly to a surface of the molten metal bath.

15. The physical vapour deposition apparatus of claim 13, wherein the at least one longitudinal slat is a single longitudinal slat positioned directly above a midpoint of a width of the molten metal bath.

16. The physical vapour deposition apparatus of claim 15, wherein the single longitudinal slat has a length that is greater than 0.7 times a spacing of the molten metal bath from the substrate.

17. The physical vapour deposition apparatus of claim 13, wherein the at least one wall is spaced from the substrate to define a gap therebetween.

18. The physical vapour deposition apparatus of claim 17, wherein the at least one longitudinal slat is sized and positioned to block metal vapour flux from entering the gap.

19. The physical vapour deposition apparatus of claim 18, wherein the longitudinal slat is positioned directly above a first side of a midpoint of a width of the molten metal bath, the longitudinal slat being sized and positioned to block metal vapour flux emitted from a second side of the midpoint of the width of the molten metal bath from entering the gap.

20. The physical vapour deposition apparatus of claim 13, further comprising temperature control elements configured to control a temperature of at least one of:
said at least one wall; and
said at least one longitudinal slat.
